(19) United States
(12) Patent Application Publication
(10) Pub. No.: US 2026/0310065 A1
(43) Pub. Date: Oct. 8, 2026

(54) METHOD AND SYSTEM FOR TRAINING A PREDICTION MODEL TO GENERATE A TWO-DIMENSIONAL-ELEMENT REPRESENTATION OF A MASK PATTERN

(71) Applicant: ASML NETHERLANDS B.V., Veldhoven (NL)

(72) Inventors: Ya LUO, Saratoga, CA (US); Robert Elliott BOONE, San Jose, CA (US); Yen-Wen LU, Saratoga, CA (US); Rafael C. HOWELL, Santa Clara, CA (US)

(73) Assignee: ASML NETHERLANDS B.V., Veldhoven (NL)

(21) Appl. No.: 19/482,729

(22) PCT Filed: May 3, 2024
(86) PCT No.: PCT/EP2024/062365

§ 371 Date: Nov. 7, 2025

Related U.S. Application Data
(60) Provisional application No. 63/469,755, filed on May 30, 2023.

(51) Int. Cl. G03F 1/36; G03F 1/70; G03F 7/00

(52) U.S. Cl. CPC G03F 1/36; G03F 1/70; G03F 7/70441

(57) ABSTRACT

A method and system for predicting a 2D-element representation of a mask pattern. An input mask pattern corresponding to a target pattern is provided to a prediction model. The prediction model generates a 2D-element representation of an output mask pattern corresponding to the input mask pattern. The 2D-element representation includes multiple 2D elements representing a mask feature of the output mask pattern and each 2D element defines an enclosed area. One or more mask feature contours of the output mask pattern are determined based on the 2D-element representation.

### CROSS REFERENCE TO RELATED APPLICATION

This application claims priority to U.S. Application No. 63/469,755, filed May 30, 2023, and which is incorporated herein in its entirety by reference.

### TECHNICAL FIELD

The embodiments provided herein relate to semiconductor manufacturing, and more particularly to designing mask patterns.

### BACKGROUND

A lithographic apparatus is a machine that applies a desired pattern onto a target portion of a substrate. The lithographic apparatus can be used, for example, in the manufacture of integrated circuits (ICs). For example, an IC chip in a smart phone, can be as small as a person's thumbnail, and may include over 2 billion transistors. Making an IC is a complex and time-consuming process, with circuit components in different layers and including hundreds of individual steps. Errors in even one step have the potential to result in problems with the final IC and can cause device failure. High process yield and high wafer throughput can be impacted by the presence of defects.

### BRIEF SUMMARY

In some aspects, the techniques described herein relate to a method for determining a mask pattern for use with a lithography process, the method including: providing an input mask pattern corresponding to a target pattern to a prediction model; generating, using the prediction model, a two-dimensional (2D)-element representation of an output mask pattern corresponding to the input mask pattern, wherein the 2D-element representation includes multiple 2D elements representing a mask feature of the output mask pattern and each 2D element defines an enclosed area; and determining mask feature contours of the output mask pattern based on the 2D-element representation.

In some aspects, the techniques described herein relate to a method for training a prediction model to generate a 2D-element representation of a mask pattern for use with a lithography process, the method including: obtaining a set of input mask patterns and a set of 2D-element representations of a set of output mask patterns corresponding to the set of input mask patterns as training data, wherein a 2D-element representation of the set of 2D-element representations includes multiple 2D elements representing a mask feature of the mask pattern and each 2D element defines an enclosed area; and training the prediction model using the training data to generate 2D-element representations.

In some embodiments, there is provided a non-transitory computer readable medium having instructions that, when executed by a computer, cause the computer to execute a method of any of the above embodiments.

In some embodiments, there is provided an apparatus that includes a memory storing a set of instructions and a processor configured to execute the set of instructions to cause the apparatus to perform a method of any of the above embodiments.

### BRIEF DESCRIPTION OF THE DRAWINGS

Embodiments will now be described, by way of example only, with reference to the accompanying drawings in which:

FIG. 1 illustrates a block diagram of various subsystems of a lithographic projection apparatus, according to an embodiment.

FIG. 2 is a schematic diagram of a lithographic projection apparatus, according to an embodiment.

FIG. 3 illustrates an exemplary flow chart for simulating lithography in a lithographic projection apparatus, according to an embodiment.

FIG. 4 illustrates a method for placing, associating, and adjusting two-dimensional (2D)elements forming a mask feature, consistent with various embodiments.

FIG. 5 illustrates a method for obtaining a contour of a mask feature based on the 2D elements, consistent with various embodiments.

FIG. 6 illustrates a representation of the 2D-element representation using location information of 2D elements of the mask feature, consistent with various embodiments.

FIG. 7 shows a set of images representative of a 2D-element representation of a mask pattern, consistent with various embodiments.

FIG. 8 is a block diagram of an exemplary system for predicting a 2D-element representation of a mask pattern using a prediction model, consistent with various embodiments.

FIG. 9 is a block diagram for generating an image representation of a mask pattern from a target pattern, consistent with various embodiments.

FIG. 10 illustrates a contour of mask feature generated from a predicted 2D-element representation of a mask feature, consistent with various embodiments.

FIG. 11 is a flow diagram of a method for predicting a 2D-element representation of a mask pattern using a prediction model, consistent with various embodiments.

FIG. 12 is a block diagram of a system for training a prediction model to generate a 2D-element representation of a mask pattern, consistent with various embodiments.

FIG. 13 is a flow diagram of a method for training a prediction model to generate a 2D-element representation of a mask pattern, consistent with various embodiments.

FIG. 14 illustrates generation of a 2D-element representation of a mask pattern as training data for training a prediction model, consistent with various embodiments.

FIG. 15 is a block diagram that illustrates a computer system which can assist in implementing the systems and methods disclosed herein.

Embodiments will now be described in detail with reference to the drawings, which are provided as illustrative examples so as to enable those skilled in the art to practice the embodiments. Notably, the figures and examples below are not meant to limit the scope to a single embodiment, but other embodiments are possible by way of interchange of some or all of the described or illustrated elements. Wherever convenient, the same reference numbers will be used throughout the drawings to refer to same or like parts. Where certain elements of these embodiments can be partially or fully implemented using known components, only those portions of such known components that are necessary for an understanding of the embodiments will be described, and detailed descriptions of other portions of such known components will be omitted so as not to obscure the description of the embodiments. In the present specification, an embodiment showing a singular component should not be considered limiting; rather, the scope is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the scope encompasses present and future known equivalents to the components referred to herein by way of illustration.

### DETAILED DESCRIPTION

A lithographic apparatus is a machine that applies a designed pattern onto a target portion of a substrate. This process of transferring the designed pattern to the substrate is called a patterning process or a lithography process. The patterning process can include a patterning step to transfer a pattern from a patterning device (such as a mask) to the substrate. Various variations (e.g., variations in the patterning process or the lithographic apparatus) can potentially limit lithography implementation for semiconductor high volume manufacturing (HVM). Optimal proximity correction (OPC) may be utilized in mask design to optimize a mask pattern so that a mask manufactured using the mask pattern ultimately delivers light to a substrate such that the desired design layout is formed. Conventional mask optimization can include starting from target pattern polygons (e.g., representing a desired pattern to be fabricated) and extracting such polygons to serve as the basis of a mask. However, such conventional optimization of mask features can be computationally expensive as there can be many elements that need to be adjusted in order to form the optimized mask feature. Further, conventional OPC may sometimes result in mask features that violate Mask Rule Checks (MRC) rules. Some methods use machine learning (ML) models (e.g., neural network) to predict a mask image (e.g., a level-set phi image of a mask pattern), then extract polygons from the level-set image, which may be used as an input to an OPC optimization process to adjust the mask feature contour. Polygon extraction is very sensitive to the values in the phi image. A small change in pixel value may lead to a large contour shift. Conventional ML models may not provide adequate prediction accuracy, and as a result, the extracted initial polygons may have large deviation from ground truth, MRC violations, and therefore, poor lithographic performance.

Disclosed are embodiments for predicting a two-dimensional-element representation of a mask pattern using a prediction model (e.g., an ML model such as a neural network). In the two-dimensional (2D)-element representation, each mask feature may be represented using multiple 2D elements (e.g., circle, ellipse, semi-circle, a portion of a circle, etc.). Additional details regarding the 2D element representation are described in PCT Application No. PCT/EP2023/055028, the disclosure of which is incorporated by reference in its entirety. Mask feature contours may be derived from the 2D elements. The derived mask feature contours may then be provided to a mask optimization process (e.g., to further adjust the mask feature contour), which may generate an optimized mask patten that may be used to manufacture a mask to print a target pattern on a substrate.

In one embodiment, the prediction model predicts 2D-element representation data from which the 2D-element representation may be generated. The predicted 2D-element representation data may include a set of images that define a placement of 2D elements in a grid. For example, a first image may be indicative of the presence or an absence of a 2D element at a particular grid location. The second image may be indicative of a shift in x-direction of the 2D element from the particular grid location, and the third image may be indicative of a shift in y-direction of the 2D element from the particular grid location. In another example, one or more images of the set of images may also define associations between the 2D elements that defines a shape of the mask feature contour. The 2D-element representation in which each mask feature of the mask pattern is represented using multiple 2D elements may be generated using the set of images. Mask feature contours may then be generated from the 2D elements. The resulting mask pattern may then be optimized using the OPC process. In some embodiments, the prediction model may be trained to predict the 2D-element representation of the mask pattern. The training data may include an input mask pattern, which may be generated from a target pattern (e.g., GDS design layout), and a set of images indicative of the 2D-element representation of an optimized mask pattern corresponding to the input mask pattern. By having the prediction model predict a 2D-element representation, instead of a level-set image, the mask feature contours derived using the prediction is less sensitive to prediction errors (e.g., as any errors may cause minimum localized contour shift as opposed to large contour shifts of the conventional prediction techniques), and therefore, result in more accurate prediction of the mask pattern. Further, training of such a prediction model is less complex, and the prediction model is fault-tolerant, converges faster and has less over-fitting issues compared to the conventional prediction techniques.

In the present disclosure, although specific reference may be made to the manufacture of ICs, it should be explicitly understood that the description herein has many other possible applications. For example, it may be employed in the manufacture of integrated optical systems, guidance and detection patterns for magnetic domain memories, liquid crystal display panels, thin film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm). In the present document, the term “radiation source” or “source” is used to encompass all types of sources of radiation, including laser sources, incandescent sources, etc. which may include treatment of the radiation between the radiation source and the target or other parts of the optics, including filtering, collimating, focusing, etc.

A patterning device can comprise, or can form, one or more design layouts. The design layout can be generated utilizing CAD (computer-aided design) programs. This process is often referred to as EDA (electronic design automation). Most CAD programs follow a set of predetermined design rules in order to create functional design layouts/patterning devices. These rules are set based processing and design limitations. For example, design rules define the space tolerance between devices (such as gates, capacitors, etc.) or interconnect lines, to ensure that the devices or lines do not interact with one another in an undesirable way. One or more of the design rule limitations may be referred to as a “critical dimension” (CD). A critical dimension of a device can be defined as the smallest width of a line or hole, or the smallest space between two lines or two holes. Thus, the CD regulates the overall size and density of the designed device. One of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective; binary, phase-shifting, hybrid, etc.), examples of other such patterning devices include a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. Examples of other such patterning devices also include a programmable LCD array. An example of such a construction is given in U.S. Pat. No. 5,229,872, which is incorporated herein by reference.

The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping, or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

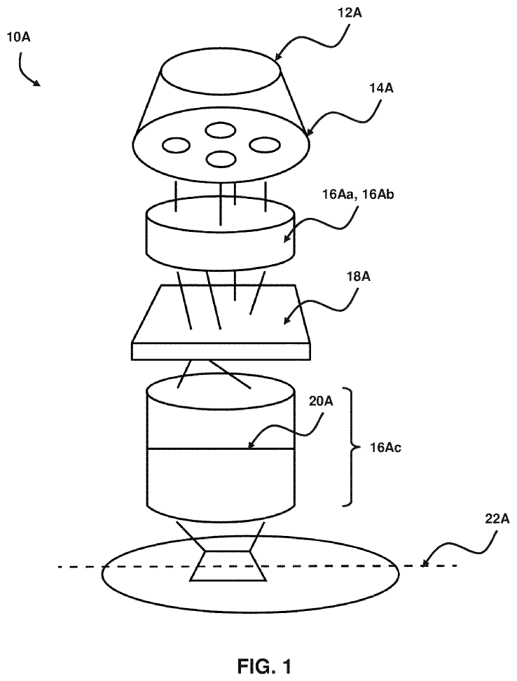

FIG. 1 illustrates a block diagram of various subsystems of a lithographic projection apparatus 10A, according to an embodiment. Major components are a radiation source 12A, which may be a deep-ultraviolet excimer laser source or other type of source including an extreme ultra violet (EUV) source (the lithographic projection apparatus itself need not have the radiation source), illumination optics which, e.g., define the partial coherence (denoted as sigma) and which may include optics 14A, 16Aa and 16Ab that shape radiation from the source 12A; a patterning device (or mask) 18A; and transmission optics 16Ac that project an image of the patterning device pattern onto a substrate plane 22A.

A pupil 20A can be included with transmission optics 16Ac. In some embodiments, there can be one or more pupils before and/or after mask 18A. As described in further detail herein, pupil 20A can provide patterning of the light that ultimately reaches substrate plane 22A. An adjustable filter or aperture at the pupil plane of the projection optics may restrict the range of beam angles that impinge on the substrate plane 22A, where the largest possible angle defines the numerical aperture of the projection optics NA=n sin(Θmax), wherein n is the refractive index of the media between the substrate and the last element of the projection optics, and Θmax is the largest angle of the beam exiting from the projection optics that can still impinge on the substrate plane 22A.

In a lithographic projection apparatus, a source provides illumination (i.e., radiation) to a patterning device and projection optics direct and shape the illumination, via the patterning device, onto a substrate. This is not to disclaim that the source does not itself provide patterning, directing, or shaping to the radiation or that patterning, directing, or shaping does not occur between the source and the projection optics. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157360, the disclosure of which is hereby incorporated by reference in its entirety. The resist model is related to properties of the resist layer (e.g., effects of chemical processes which occur during exposure, post-exposure bake (PEB) and development). Optical properties of the lithographic projection apparatus (e.g., properties of the illumination, the patterning device, and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

One aspect of understanding a lithographic process is understanding the interaction of the radiation and the patterning device. The electromagnetic field of the radiation after the radiation passes the patterning device may be determined from the electromagnetic field of the radiation before the radiation reaches the patterning device and a function that characterizes the interaction. This function may be referred to as the mask transmission function (which can be used to describe the interaction by a transmissive patterning device and/or a reflective patterning device).

The mask transmission function may have a variety of different forms. One form is binary. A binary mask transmission function has either of two values (e.g., zero and a positive constant) at any given location on the patterning device. A mask transmission function in the binary form may be referred to as a binary mask. Another form is continuous. Namely, the modulus of the transmittance (or reflectance) of the patterning device is a continuous function of the location on the patterning device. The phase of the transmittance (or reflectance) may also be a continuous function of the location on the patterning device. A mask transmission function in the continuous form may be referred to as a continuous tone mask or a continuous transmission mask (CTM). For example, the CTM may be represented as a pixelated image, where each pixel may be assigned a value between 0 and 1 (e.g., 0.1, 0.2, 0.3, etc.) instead of binary value of either 0 or 1. In an embodiment, CTM may be a pixelated gray scale image, where each pixel having values (e.g., within a range [−255, 255], normalized values within a range [0, 1] or [−1, 1] or other appropriate ranges).

The thin-mask approximation, also called the Kirchhoff boundary condition, is widely used to simplify the determination of the interaction of the radiation and the patterning device. The thin-mask approximation assumes that the thickness of the structures on the patterning device is very small compared with the wavelength and that the widths of the structures on the mask are very large compared with the wavelength. Therefore, the thin-mask approximation assumes the electromagnetic field after the patterning device is the multiplication of the incident electromagnetic field with the mask transmission function. However, as lithographic processes use radiation of shorter and shorter wavelengths, and the structures on the patterning device become smaller and smaller, the assumption of the thin-mask approximation can break down. For example, interaction of the radiation with the structures (e.g., edges between the top surface and a sidewall) because of their finite thicknesses (“mask 3D effect” or “M3D”) may become significant. Encompassing this scattering in the mask transmission function may enable the mask transmission function to better capture the interaction of the radiation with the patterning device. A mask transmission function under the thin-mask approximation may be referred to as a thin-mask transmission function. A mask transmission function encompassing M3D may be referred to as a M3D mask transmission function.

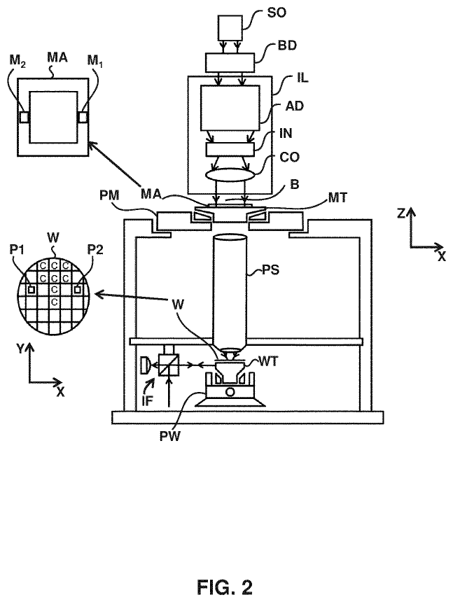

FIG. 2 schematically depicts an exemplary lithographic projection apparatus whose illumination source could be optimized utilizing the methods described herein. The apparatus comprises:
an illumination system IL, to condition a beam B of radiation. In this particular case, the illumination system also comprises a radiation source SO;
a first object table (e.g., mask table, patterning device table or reticle stage) MT provided with a patterning device holder to hold a patterning device MA (e.g., a reticle), and connected to a first positioner to accurately position the patterning device with respect to item PS;
a second object table (substrate table or wafer stage) WT provided with a substrate holder to hold a substrate W (e.g., a resist-coated silicon wafer), and connected to a second positioner to accurately position the substrate with respect to item PS;
a projection system (“lens”) PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive mask). However, in general, it may also be of a reflective type, for example (with a reflective mask). Alternatively, the apparatus may employ another kind of patterning device as an alternative to the use of a classic mask; examples include a programmable mirror array or LCD matrix.

The source SO (e.g., a mercury lamp or excimer laser) produces a beam of radiation. This beam is fed into an illumination system (illuminator) IL, either directly or after having traversed conditioning means, such as a beam expander Ex, for example. The illuminator IL may comprise adjusting means AD for setting the outer or inner radial extent (commonly referred to as o-outer and o-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

It should be noted with regard to FIG. 2 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F₂ lasing).

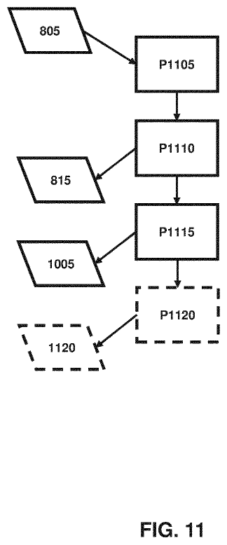

The beam B subsequently intercepts the patterning device MA, which is held on a patterning device table MT. Having traversed the patterning device MA, the beam B passes through the lens PS, which focuses the beam B onto a target portion C of the substrate W. With the aid of the second positioning means (and interferometric measuring means IF), the substrate table WT can be moved accurately, e.g., so as to position different target portions C in the path of beam B. Similarly, the first positioning means can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted in FIG. 11. However, in the case of a wafer stepper (as opposed to a step-and-scan tool) the patterning device table MT may just be connected to a short stroke actuator, or may be fixed.

The depicted tool can be used in two different modes:
In step mode, the patterning device table MT is kept essentially stationary, and an entire patterning device image is projected in one go (i.e., a single “flash”) onto a target portion C. The substrate table WT is then shifted in the x or y directions so that a different target portion C can be irradiated by the beam B;
In scan mode, essentially the same scenario applies, except that a given target portion C is not exposed in a single “flash”. Instead, the patterning device table MT is movable in a given direction (the so-called “scan direction”, e.g., the y direction) with a speed v, so that the projection beam B is caused to scan over a patterning device image; concurrently, the substrate table WT is simultaneously moved in the same or opposite direction at a speed V=Mv, in which M is the magnification of the lens PS (typically, M=¼ or ⅕). In this manner, a relatively large target portion C can be exposed, without having to compromise on resolution.

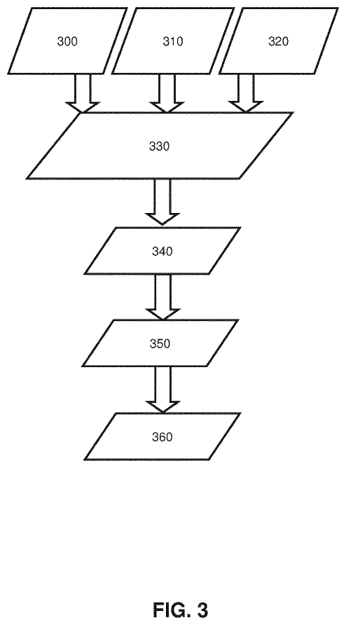

FIG. 3 illustrates an exemplary flow chart for simulating lithography in a lithographic projection apparatus, according to an embodiment. As will be appreciated, the models may represent a different patterning process and need not comprise all the models described below. A source model 300 represents optical characteristics (including radiation intensity distribution, bandwidth and/or phase distribution) of the illumination of a patterning device. The source model 300 can represent the optical characteristics of the illumination that include, but not limited to, numerical aperture settings, illumination sigma (σ) settings as well as any particular illumination shape (e.g., off-axis radiation shape such as annular, quadrupole, dipole, etc.), where o (or sigma) is outer radial extent of the illuminator.

A projection optics model 310 represents optical characteristics (including changes to the radiation intensity distribution and/or the phase distribution caused by the projection optics) of the projection optics. The projection optics model 310 can represent the optical characteristics of the projection optics, including aberration, distortion, one or more refractive indexes, one or more physical sizes, one or more physical dimensions, etc.

The patterning device/design layout model module 320 captures how the design features are laid out in the pattern of the patterning device and may include a representation of detailed physical properties of the patterning device, as described, for example, in U.S. Pat. No. 7,587,704, which is incorporated by reference in its entirety. In an embodiment, the patterning device/design layout model module 320 represents optical characteristics (including changes to the radiation intensity distribution and/or the phase distribution caused by a given design layout) of a design layout (e.g., a device design layout corresponding to a feature of an integrated circuit, a memory, an electronic device, etc.), which is the representation of an arrangement of features on or formed by the patterning device. Since the patterning device used in the lithographic projection apparatus can be changed, it is desirable to separate the optical properties of the patterning device from the optical properties of the rest of the lithographic projection apparatus including at least the illumination and the projection optics. The objective of the simulation is often to accurately predict, for example, edge placements and CDs, which can then be compared against the device design. The device design is generally defined as the pre-OPC patterning device layout, and will be provided in a standardized digital file format such as GDSII or OASIS.

An aerial image 330 can be simulated from the source model 300, the projection optics model 310 and the patterning device/design layout model module 320. An aerial image (AI) is the radiation intensity distribution at substrate level. Optical properties of the lithographic projection apparatus (e.g., properties of the illumination, the patterning device, and the projection optics) dictate the aerial image.

A resist layer on a substrate is exposed by the aerial image and the aerial image is transferred to the resist layer as a latent “resist image” (RI) therein. The resist image (RI) can be defined as a spatial distribution of solubility of the resist in the resist layer. A resist image 350 can be simulated from the aerial image 330 using a resist model 340. The resist model can be used to calculate the resist image from the aerial image, an example of which can be found in U.S. Pat. No. 8,200,468, the disclosure of which is hereby incorporated by reference in its entirety. The resist model 340 typically describes the effects of chemical processes which occur during resist exposure, post exposure bake (PEB) and development, in order to predict, for example, contours of resist features formed on the substrate and so it typically related only to such properties of the resist layer (e.g., effects of chemical processes which occur during exposure, post-exposure bake and development). In an embodiment, the optical properties of the resist layer, e.g., refractive index, film thickness, propagation, and polarization effects—may be captured as part of the projection optics model 310.

So, in general, the connection between the optical and the resist model is a simulated aerial image intensity within the resist layer, which arises from the projection of radiation onto the substrate, refraction at the resist interface and multiple reflections in the resist film stack. The radiation intensity distribution (aerial image intensity) is turned into a latent “resist image” by absorption of incident energy, which is further modified by diffusion processes and various loading effects. Efficient simulation methods that are fast enough for full-chip applications approximate the realistic 3-dimensional intensity distribution in the resist stack by a 3-dimensional aerial (and resist) image.

In an embodiment, the resist image 350 can be used an input to a post-pattern transfer process model module 360. The post-pattern transfer process model module 360 defines performance of one or more post-resist development processes (e.g., etch, development, etc.).

Simulation of the patterning process can, for example, predict contours, CDs, edge placement (e.g., edge placement error), etc. in the resist and/or etched image. Thus, the objective of the simulation is to accurately predict, for example, edge placement, and/or aerial image intensity slope, and/or CD, etc. of the printed pattern. These values can be compared against an intended design to, e.g., correct the patterning process, identify where a defect is predicted to occur, etc. The intended design is generally defined as a pre-OPC design layout which can be provided in a standardized digital file format such as GDSII or OASIS or other file format.

Thus, the model formulation describes most, if not all, of the known physics and chemistry of the overall process, and each of the model parameters desirably corresponds to a distinct physical or chemical effect. The model formulation thus sets an upper bound on how well the model can be used to simulate the overall manufacturing process.

The following paragraphs describe a system and a method for predicting a 2D-element representation of a mask pattern. A prediction model (e.g., an ML model such as a neural network) is trained to predict the 2D-element representation based on an input mask pattern (e.g.,, generated from a target pattern to be printed on a substrate). The 2D-element representation predicted by the prediction model is a multi-channel output (although it can be a single-channel output as described below) which includes a set of images that is indicative of location information of 2D elements representing a mask feature. The training data (e.g., ground truth), which includes the input mask pattern and the set of images indicative of the location information of the 2D elements may be generated in a number of ways.

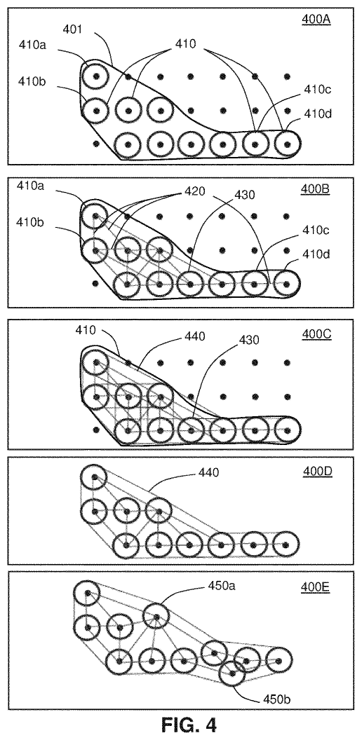

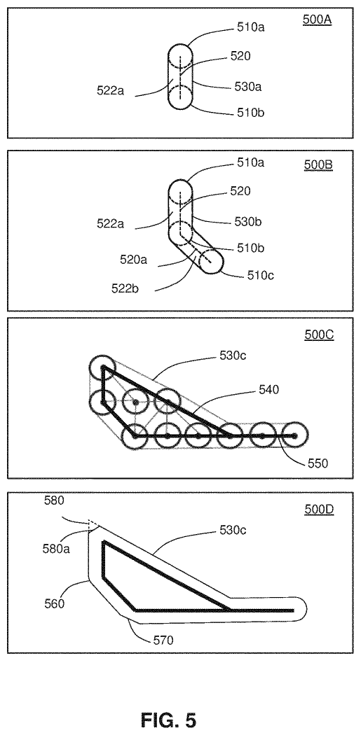

FIGS. 4 and 5 provide a brief introduction of a 2D-element representation of a mask feature and generating a mask feature contour from the 2D-element representation, respectively.

FIG. 4 illustrates a method for placing, associating, and adjusting 2D elements forming a mask feature, consistent with various embodiments. In some embodiments, determining a mask pattern (or portions thereof) for use with a lithographic process can include assigning locations of 2D elements 410 based on a target pattern. As shown in the first (top) portion 400A of FIG. 4, the shape of the mask feature 401 can be represented by a collection of 2D elements 410 (in this example shown as circles). The 2D elements are located at different positions to form the shape of the mask feature, as illustrated with a grid shown by the dots for reference. The dots of the grid locations may not be generated, they are just shown illustration purposes only. In some embodiments, the grid may be a collection of pixels in an image. Four of the 2D elements are labeled as 410a, 410b, 410c and 410d. Though described further herein at least with reference to FIG. 5, it can be seen that a contour formed around the 2D elements (e.g., the circles having a diameter of at least a minimum width as specified by an MRC rule) can inherently and automatically satisfy the MRC rule regardless of the locations of the 2D elements.

The next panel 400B in FIG. 4 depicts an example of associating the 2D elements based on association criteria to form a cluster 430 that represents a mask feature. The associations 420 are depicted as line segments between the 2D elements. The 2D elements that are associated can then be utilized, as explained further herein, to form cluster 430 that has a shape corresponding to mask feature 401. In FIG. 4, all of the 2D elements shown are part of cluster 430. Not all 2D elements in a cluster need be associated with each other as the elements that are associated are dependent on the mask feature optimization. For example, 2D element 410 a in the upper left is not associated with 2D element 410d on the lower right, though through their associations with other 2D elements are part of the same cluster 430. In some embodiments, the association criteria may be rule-based criteria. For example, one association criterion may be distance-based in which two 2D elements may be associated with each other if they are within a prescribed distance. While the prescribed distance can be arbitrarily set by user or otherwise manipulated by the system, in some embodiments, the prescribed distance may be based on an MRC rule for a minimum width of the mask feature. In some embodiments, two 2D elements may be associated with each other based on a prediction from a prediction model, as described at least with reference to FIGS. 7, 8 and 12-13.

The middle panel 400C in FIG. 4 depicts an exemplary contour 440 around cluster 430. As described in further detail herein, such as with reference to FIG. 5, contour 440 can be generated to encompass an area formed by the 2D elements and a region between the 2D elements. Accordingly, the contour can be an outer contour of a cluster that corresponds to an outer edge of a mask feature. Similarly, for mask features having an inner edge such as a donut-shaped mask feature, the contour can be an inner contour of the cluster that corresponds to an inner edge of the mask feature.

The next panel 400D is similar to the middle panel, again showing 2D elements 410, associations 420, cluster 430, and contour 440, but without showing the lines forming the regions between 2D elements or showing the mask feature 401. Here, contour 440 is more clearly visible and surrounding the cluster of 2D elements.

The bottom panel 400E in FIG. 4 depicts adjusting the 2D elements of the cluster 430 to vary the mask feature formed by the cluster 430. In some embodiments, the adjusting of mask features can be based on a simulation associated with the lithography process (e.g., as described at least with reference to FIG. 3), OPC models, etc. In other embodiments, the adjusting of mask features can be based on geometric properties of the mask pattern (e.g., widths, separations, etc.) and based on rules prescribed for OPC (e.g., adding serifs, bias, hammerhead, SRAFs, etc. on the main features). In some embodiments where adjustments are based on simulations, a mask generation process, as in SMO or OPC, etc., can optimize mask features by adjusting any combination of the 2D elements of any of the clusters formed for the simulated mask. In this example, 2D element 450 a is shown at a slightly different position and 2D element 450b has been added (with nearby 2D elements also moved slightly). As used herein, “adjusting” a 2D element means to move, change the shape of, or add/subtract a 2D element. For example, the centers of the circular 2D elements can be moved as needed to optimize the mask. In other implementations, the radius of the circular 2D elements can be changed as part of the optimization process. With such methods of determining/adjusting the contours of mask features, any of the disclosed methods can include manufacturing a mask from a mask pattern that includes contours generated from adjusted 2D elements.

The present disclosure contemplates that many kinds of 2D elements can be utilized. As the 2D elements can be utilized to define at least a particular dimension (e.g., a CD, minimum spacing between mask features, etc.), and in some cases a particular area (e.g., a minimum area allowed for a mask feature), the 2D elements can define a non-zero area (e.g., as distinct from a point). In some embodiments, a 2D element is a two-dimensional (2D) element. For example, the 2D element can be circular, or more generally, elliptical. The 2D elements can be the same size or can vary in size within a cluster or among clusters. It is not necessary that the 2D elements are circular/elliptical. For example, the 2D elements can be a polygon (e.g., square, triangle, rectangle, hexagon, etc.) or a suitable arbitrary shape. In such implementations, the contour can be inscribed around the vertices or inscribed against the edges. Such 2D elements can define an enclosed area (e.g., the area of the circles, as shown), at least partially enclosed area or semi-enclosed (e.g., semi-circle). While shapes such as circles, polygons, etc. are examples of enclosed areas, in some embodiments a 2D element can be effectively represented by an arc or other similar structure. For example, the same contour in the bottom panel of FIG. 4 could be generated by positioning arc segments having the same centers as the circles and with the arc segments appropriately oriented and having sufficient length to produce the depicted contour. Accordingly, other 2D elements equivalent to the 2D elements depicted herein may be considered within the scope of the present disclosure.

FIG. 5 illustrates a method for obtaining a contour of a mask feature based on the 2D elements, consistent with various embodiments. The cluster of 2D elements can be contoured in any suitable way without departing from the scope of the present disclosure, with one implementation depicted in FIG. 5. The top portion 500A of FIG. 5 depicts two exemplary associated 2D elements 510a and 510b. A virtual line segment 520 can connect the centers of the 2D elements. It is not necessary that the system generates the virtual line segment 520 (it is provided here for explanatory purposes). To contour 530a around the two-dimension elements, the virtual line segment 520 can be offset on either side by a distance equal to the radius of the 2D elements. This can then form what are referred to herein as “sub-areas” (the areas of the 2D elements and the area between them based on the offset lines) with one shown as sub-area 522a. In implementations where the 2D elements are not the same size, the offsetting can be such that the offset distance transitions from one radius to the other. However, it will be appreciated that this discussion is merely exemplary. The offset distance or a sub-area can be defined in any other suitable manner and a mask feature may have many such sub-areas. The area enclosed by the contour 530a can be the area occupied by the sub-areas and any corresponding areas interior to a connected collection of sub-areas (e.g., the area of the sub-areas around the perimeter of a mask feature and the area such a perimeter might enclose).

The next portion 500B extends the above example to include 2D element 510c. Another virtual line segment 520a is shown between 510b and 510 c as well as the corresponding offset line segments that form part of contour 530b. Accordingly, in various implementations, processes similar to that described above can include generating sub-areas (e.g., 522a and 522b) of the contour by applying a polygon offsetting operation to pairs (e.g., 510a/b and 510b/c) of the associated 2D elements. The process can then include computing the union of the sub-areas, wherein the contour 530b is the union of the sub-areas. As the depicted 2D elements can form a cluster, the system can thereby generate a contour of the cluster based on the 2D elements. In this example, the contour corresponds to the outer contour of all the sub-areas in the cluster that form the perimeter of the cluster. This process can be extended to an arbitrary number and configuration of 2D elements as shown by the bottom portion 500C, showing contour 530c.

While the example of FIG. 5 in panels 500A-C were provided to provide an exemplary step-by-step method of contouring, in some implementations the contouring can be performed with substantially fewer steps. For example, once 2D elements are determined that will form the basis of a mask shape, such 2D elements can then form a single shape (which may comprise any combination of polygons and line segments). This shape can then be treated as a “polygon” (again, not necessarily strictly a polygon as it may have portions that are line segments) and this “polygon” can then be contoured by performing a polygon offsetting operation, according to any of the examples herein, with a few described below.

In some embodiments, a “polygon offsetting” operation can be performed where a polygon to be contoured can be defined by selecting locations of 2D elements (e.g., centers) that correspond to a desired mask feature. One example of such a polygon 540 is shown in 500C by the heavier lines, where various line segments connecting certain centers of 2D elements are shown. Polygon 540 (including exemplary additional line segment 550) can then be offset (e.g., by the radius of the 2D elements) to form the depicted contour 530c. Though not shown in the example of FIG. 5, any inner regions (e.g., as in a “donut-shaped” mask feature) can be similarly defined, contoured, and shaped as described herein.

The defined outer contour can be further processed in any suitable technique. As seen from the examples of circular 2D elements in FIG. 4 and FIG. 5, some portions of the determined contours are naturally rounded based on the radius of the 2D elements. However, in some locations such as the concave portions of the contour 530a-530c, the disclosed methods can also include performing corner rounding or any other type of smoothing operations on the outer contour. One method of corner rounding can include performing spline interpolation between two points on either side of a corner. In some embodiments, the spline interpolation can modify the contour to be smooth but may bring it out from touching a 2D element. Such deviations can be acceptable as they may further reinforce compliance with a minimum width MRC rule.

In some embodiments, shown in panel 500D, rather than a rounded corner 560, the system can generate a “squared corner” 570 around a vertex of a contoured polygon such that the intersecting segments that would ordinarily make a sharp vertex are instead met with a third line segment (e.g., similar to a chamfer). Another option can be allowing the line segments to meet to form a “mitered corner” 580, however in certain embodiments this may cause an undesirable extension of the contour (e.g., which may be past a prescribed limit of distance from the associated vertex). In such cases, the system can square the mitered corner 580 to become another squared corner 580a such that the contour does not extend beyond the prescribed limit. Additional details of generating the 2D-element representation or generating the mask feature contour from the 2D-element representation is described in PCT Application No. PCT/EP2023/055028, the disclosure of which is incorporated by reference in its entirety.

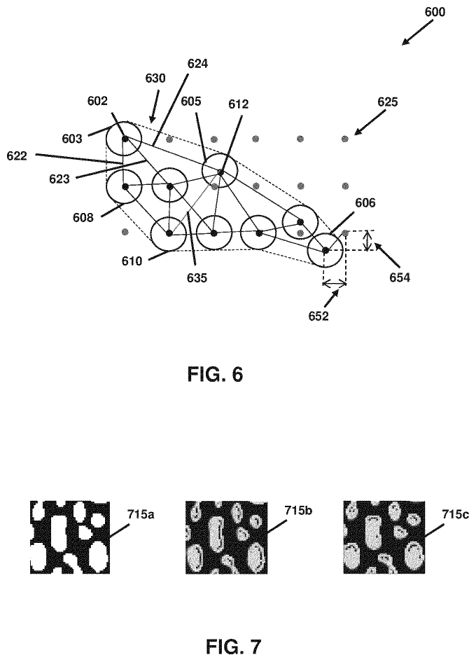

In some embodiments, the 2D-element representation may be expressed using location information of the 2D elements representing the mask feature. FIG. 6 illustrates a representation of the 2D-element representation using location information of 2D elements of the mask feature, consistent with various embodiments. For example, consider a 2D-element representation 600 of a mask feature 630 shown in FIG. 6. In some embodiments, the 2D-element representation 600 is similar to the 2D-element representation in panel 400E of FIG. 4. The 2D elements may be assigned locations of a grid (e.g., a collection of pixels), such as grid 625. Note that grid 625 shown as dots in FIG. 6 is imaginary, is for illustration purposes only, and is not generated by the system. A grid location may correspond to one or more pixels in the image, and a resolution or size of the grid may be user-defined. For example, the grid may be “10×10” or “25×25” grid locations, where each grid location may correspond to one pixel or more than pixel. In some embodiments, grid 625 may be considered as a 2D matrix.

The 2D elements such as a first 2D element 603 may be represented using location information. The 2D elements may be assigned co-ordinates of grid 625. In some embodiments, a grid coordinate that is assigned to the 2D element depends on a geometrical attribute of the 2D element. In the example of FIG. 6, a grid coordinate that is assigned to the 2D element may be the grid coordinate that is closest to the center of the 2D element. For example, for the first 2D element 603, a grid coordinate (1,1) that is closest to the center 602 of the first 2D element 603 is assigned as a location of the first 2D element 603. Similarly, a grid coordinate (2,3) that is closest to center 612 of a second 2D element 605 is assigned as the location of the second 2D element 605. Accordingly, the location information (e.g., grid coordinates) may be generated for all 2D elements in the 2D-element representation 600. Note that while grid coordinates are used to indicate the location information other parameters may be used as well. For example, (x, y) coordinates may be used instead of the matrix style coordinates.

In some embodiments, the location information may also include presence information, which may be a binary value that is indicative of a presence or absence of a 2D element at a particular grid location. For example, for a first grid coordinate (1,1), the presence information may include a value of “1″ indicating a presence of the 2D element at the first grid coordinate (1,1). Similarly, for a second grid coordinate (1,2) the presence information may include a value of ”0″ indicating an absence of the 2D element at the second grid coordinate (1,2). Accordingly, the location information may include presence information for all grid coordinates. The binary value may be expressed in a number of ways (e.g., “0” or “1”, “yes” or “no”, “true” or “false” etc.).

In some embodiments, the location information may also include an amount of shift or displacement of a 2D element from a particular grid location. In some embodiments, the location information may provide the shift values in different directions (e.g., x-direction and y-direction) separately. For example, the location information may include displacement information such as ((6,3), αₓ), which indicates that a 2D element (e.g., fifth 2D element 606) is displaced by an amount 652, αₓ, in x-direction from the grid co-ordinate (6,3). Similarly, the location information may include displacement information such as ((6,3), α_{y}), which indicates that a 2D element (e.g., fifth 2D element 606) is displaced by an amount 654, α_{y}, in y-direction from the grid co-ordinate (6,3).

In some embodiments, the location information may also include association information between the 2D elements. For example, the association information may indicate which 2D element is associated with which other 2D element. The association information may be indicated in various ways. In a first example, the associations 622, 623 and 624 may be indicated as ((1,1), (2,1), (2,2)), which indicates that a 2D element in the grid coordinate (1,1) (e.g., first 2D element 603) is associated with 2D elements in the grid coordinates (2,1) (e.g., third 2D element 608), (2,2) and (2,3) (e.g., second 2D element 605). In a second example, the association information may be indicated for x and y directions separately. For example, the x-direction association information for a 2D element at grid coordinate (2,1) may be expressed as ((2,1), (2,2)) indicates that a 2D element in the grid coordinate (2,1) (e.g., third 2D element 608) is associated with another 2D element in the x-direction at grid coordinate (2,2). Similarly, the y-direction association information for the 2D element at the grid coordinate (2,1) may be expressed as ((2,1), (1,1), (3,2)), which indicates that a 2D element in the grid coordinate (2,1) (e.g., third 2D element 608) is associated with other 2D elements in the y-direction at grid coordinate (1,1) (e.g., first 2D element 603) and (3,2) (e.g., fourth 2D element 610). In a third example, the association information may be indicated as a binary value, which indicates whether a 2D element at a particular grid location is associated with a 2D element in a neighboring location in one or more directions. For example, example, the x-direction association information for a 2D element at grid coordinate (2,1) may be expressed as ((2,1), 1), which indicates that a 2D element in the grid coordinate (2,1) (e.g., third 2D element 608) is associated with a 2D element in the neighboring grid in the x-direction—grid coordinate (2,2). Similarly, the y-direction association information for the 2D element at the grid coordinate (2,1) may be expressed as ((2,1), 0), which indicates that a 2D element in the grid coordinate (2,1) (e.g., third 2D element 608) is not associated with a 2D element in the neighboring grid location in the y-direction—grid coordinate (3,1).

In some embodiments, the above information such as the presence information, location information, displacement information, association information, etc. may be encoded into a set of images from which the 2D-element representation 600 may be derived. While the above information may be used to generate the set of images, in some embodiments, the set of images may be derived from a level-set image of a mask pattern. FIG. 7 shows a set of images representative of a 2D-element representation of a mask pattern, consistent with various embodiments. In the example of FIG. 7, the first image 715a may be a binary image in which each pixel value may indicate the presence or absence of a 2D element at the corresponding grid location. For example, a white color pixel may be representative of the presence of a 2D element, or a portion thereof, at the corresponding grid location, and a black color pixel may be representative of an absence of a 2D element at the corresponding grid location.

The second image 715b may be indicative of displacement information of the 2D elements in the first direction. For example, each pixel value in the second image 715b may be indicative of the amount of displacement of a 2D element in an x-direction from the location of that pixel.

A third image 715c may be indicative of displacement information of the 2D elements in a second direction. For example, each pixel value in the third image 715c may be indicative of the amount of displacement of a 2D element in a y-direction from the location of that pixel.

The set of images may include lesser or a greater number of images than depicted in FIG. 7. For example, the set of images may not include the first image 715a in which case the presence information is derived from the second image 715b and the third image 715c. In some embodiments, the set of images may include additional images such as images that are indicative of association information. One or more images may be generated to depict associations in different directions. For example, a first association image may be a binary image that is indicative of an association in a first direction (e.g., x-direction). Each pixel value may indicate whether a 2D element at a particular location is associated with a 2D element in the neighboring location in the x-direction. In another example, a second association image may be a binary image that is indicative of an association in a second direction (e.g., y-direction). Each pixel value may indicate whether a 2D element at a particular location is associated with a 2D element in the neighboring location in the y-direction. In yet another example, a third association image may be a binary image that is indicative of an association in a third direction (e.g., Northeast (NE)-direction). Each pixel value may indicate whether a 2D element at a particular location is associated with a 2D element in the neighboring location in the NE-direction. For example, the pixel value of a pixel corresponding to the grid coordinate (3,2) may be indicative of the association 635 between the 2D element at the grid coordinate (3,2) and the 2D element at the grid coordinate (2,3). Other images for associations in other directions (e.g., Northwest direction, Southeast direction, Southwest direction) may also be generated.

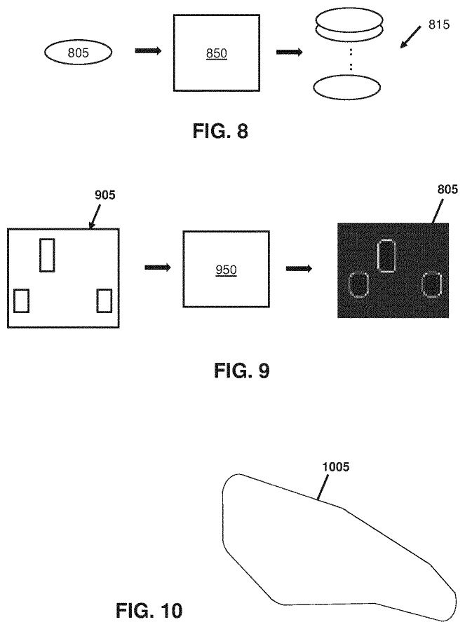

In some embodiments, training a prediction model to generate a set of images (e.g., one or more of the above set of images) that is representative of a 2D-element representation is more efficient than training the prediction model to generate the mask pattern itself. For example, such a ML model may be more fault tolerant, converge faster or consume lesser computing resources than training the ML model to generate the mask pattern itself. After the set of images are generated, the 2D-element representation may be derived or constructed from the set of images, and mask feature contours may be constructed to generate an output mask pattern. FIGS. 8-11 describe generating or predicting a 2D-element representation of a mask pattern using an ML model.

FIG. 8 is a block diagram of an exemplary system for predicting a 2D-element representation of a mask pattern using a prediction model, consistent with various embodiments. FIG. 11 is a flow diagram of a method for predicting a 2D-element representation of a mask pattern using a prediction model, consistent with various embodiments.

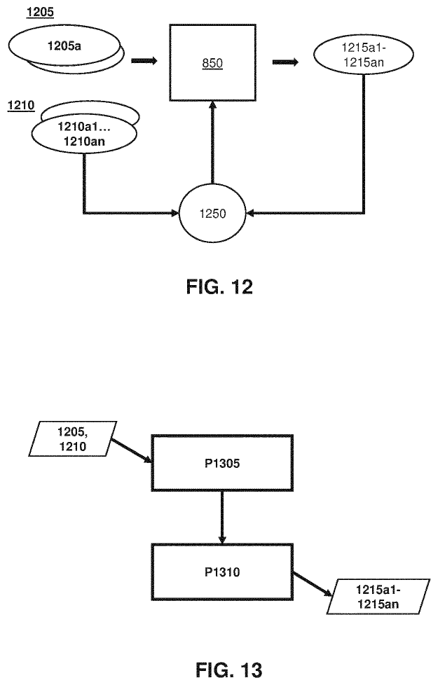

At process P1105 of FIG. 11, an input mask pattern 805 is provided to a prediction model 850. In some embodiments, the prediction model 850 is an ML model (e.g., a neural network model) that is trained to predict the 2D-element representation of the mask pattern. Additional details of training the prediction model 850 is described at least with reference to FIGS. 12 and 13.

The input mask pattern 805 may be an image representation of an initial version of a mask pattern that is to be printed on a substrate. In some embodiments, the input mask pattern 805 may be generated from a target pattern (e.g., GDS layout), as shown in FIG. 9. FIG. 9 is a block diagram for generating an image representation of a mask pattern from a target pattern, consistent with various embodiments. An imaging component 950 may generate the input mask pattern 805 from a target pattern 905, which is a design layout of a pattern to be printed on the substrate. The imaging component 950 may use any of a known number of methods to generate the input mask pattern 805. For example, the imaging component 950 may use a rasterization process to generate the input mask pattern 805 from the target pattern 905. In the rasterization process, the target pattern is decomposed into trapezoids and all the trapezoids are rasterized into a temporary buffer. Then transmission and phase are applied on the buffer to create the image of the input mask pattern 805. In some embodiments, the corners of the features of the target pattern 905 may be rounded, the edges may be smoothed (e.g., antialiasing), pixel values may be filled (e.g., converted to a grayscale image) as part of the rasterization process. In some embodiments, the generation of the input mask pattern 805 may not include simulating the lithography process (e.g., described at least with reference to FIG. 3).

Referring back to FIG. 11, at process P1110, the prediction model 850 generates a set of images 815 that is representative of the 2D-element representation of an output mask pattern (e.g., which is an intermediate optimized version of the input mask pattern). The set of images 815 may be indicative of location information of the 2D elements in the 2D-element representation. In some embodiments, the location information includes information regarding grid locations assigned to the 2D elements and displacements of the 2D elements from the assigned grid locations. The set of images 815 may include one or more of the images described at least with reference to FIG. 7 above. For example, the set of images 815 includes a binary image (e.g., the first image 715a) that is indicative of presence or absence of a 2D element at a specified grid location. The set of images 815 may include a second image (e.g., the second image 715b) that is indicative of the amount of displacement of a 2D element from a specified grid location in a first direction (e.g., x-direction), and a third image (e.g., third image 715c) that is indicative of an amount of displacement of the 2D element from the specified grid location in the second direction (e.g., y-direction). In some embodiments, the set of images 815 may not include the first image 715a, in which case, the presence information may be derived from the second image 715b and the third image 715c.

In some embodiments, the set of images 815 may also include images that are indicative of associations between the 2D elements of the 2D-element representation. For example, a first association image may be a binary image that is indicative of whether a 2D element at a particular location is associated with a 2D element in the neighboring location in a first direction (e.g., X-direction). A second association image may be a binary image that is indicative whether a 2D element at a particular location is associated with a 2D element in the neighboring location in a second direction (e.g., y-direction). In some embodiments, the association information may not be predicted by the prediction model. The 2D elements may be associated based on association criteria. In some embodiments, the association criteria may be rule-based criteria. For example, one association criterion may be distance-based in which two 2D elements may be associated with each other if they are within a prescribed distance, as described at least with reference to FIG. 4. In some embodiments, the prediction model 850 is referred to as a single-channel input and multi-channel output prediction model as a number of images (e.g., set of images 815) are generated as an output for an input of a single image (e.g., input mask pattern 805). In embodiments where the prediction model 850 outputs a single image (e.g., only presence information such as the first image 715a), the prediction model 850 is referred to as a single-channel input and single-channel output prediction model.

Note that the prediction model can be trained to predict any number of images based on the desired information. For example, if only the presence information of the 2D elements is desired, then the prediction model may be trained to predict a single image (e.g., the first image 715a). In the single-channel output embodiments, the displacement information (e.g., displacement of the 2D element from a particular grid location) may be considered to be “0”. In another example, if only the displacement information of the 2D elements in two directions is desired, then the prediction model may be trained to predict two images (e.g., the second image 715b, and the third image 715c). The presence information of the 2D elements at various locations may be derived from the displacement information included in the two images. In another example, if the presence information and displacement information of the 2D elements in two directions are desired, then the prediction model may be configured to generate three images (e.g., the first image 715a, the second image 715b, and the third image 715c). In yet another example, if the presence information, displacement information of the 2D elements in two directions, and association information of the 2D elements in two directions are desired, then the prediction model may be configured to generate five images (e.g., the first image 715a, the second image 715b, the third image 715c and two additional images that are indicative of an association of 2D element in the two directions (e.g., x direction—to left of the 2D element and y direction—to below the 2D element), respectively. In yet another example, if the presence information, displacement information of the 2D elements in two directions, and association information of the 2D elements in four directions are desired, then the prediction model may be configured to generate seven images (e.g., the first image 715a, the second image 715b, the third image 715c and four additional images that are indicative of an association of 2D element in the two directions (e.g., x direction—two images that are indicative of association to left and right of the 2D element, respectively, and y direction—two images that are indicative of association to one above and below the 2D element), respectively. Various such outputs are possible.

A 2D-element representation is generated based on the set of images 815. For example, the 2D-element representation may be similar to the 2D-element representation 600 of a mask feature 630, or the 2D-element representation of FIG. 4 in bottom panel 400E of a mask feature 401, and may be generated using the various information derived from the set of images 815. In some embodiments, the 2D-element representation is generated for all the mask features of the output mask pattern.

At process P1115, mask feature contours are generated for the mask features based on the 2D elements in the 2D-element representation. In some embodiments, a mask feature contour may be constructed using polygon-offsetting or clustering of 2D elements, as described at least with reference to FIGS. 4 and 5. For example, a 2D-element may be associated with one or more other 2D elements based on the association criteria or association information obtained from the set of images predicted by the prediction model to generate one or more clusters of the 2D elements to form the shape of a mask feature, and then a mask feature contour may be generated from the 2D elements, as described at least with reference to FIG. 5. For example, the mask feature contour 1005, as illustrated in FIG. 10, may be generated for the mask feature 630 based on the 2D elements of the 2D-element representation 600. The mask feature contours are generated for all the mask features, thus generating an output mask pattern.

In some embodiments, at process P1120, the output mask pattern may be further optimized by performing a mask optimization process, such as OPC, to generate an optimized mask pattern 1120. A mask or a patterning device may be manufactured based on the optimized mask pattern 1120 for use in a lithographic process to print a target pattern on the substrate.

FIGS. 12-14 illustrate training of the prediction model 850 to generate a 2D-element representation of a mask pattern. FIG. 12 is a block diagram of a system for training a prediction model to generate a 2D-element representation of a mask pattern, consistent with various embodiments. FIG. 13 is a flow diagram of a method for training a prediction model to generate a 2D-element representation of a mask pattern, consistent with various embodiments.

At process P1305, training data is obtained for training the prediction model. In some embodiments, the training data includes a set of input mask pattern images 1205 and several sets of images 1210 in which each set of images is representative of a 2D-element representation of an output mask pattern of a corresponding input mask pattern. For example, the training data may include an input mask pattern 1205a and a set of images 1210a1-1210an corresponding to the 2D-element representation of an output mask pattern (e.g., an optimized version of the input mask pattern 1205a).

In some embodiments, the input mask pattern 1205a is an image generated from a target pattern, e.g., using an imaging component 950 as described at least with reference to FIG. 9.

In some embodiments, the set of images 1210a1-120an may be similar to the set of images 815 that is indicative of location information, presence information, displacement information, association information, etc. of the 2D elements of the 2D element representation. The set of images 1210al-1210an may be generated from a 2D-element representation, which may be generated in a number of ways. In a first method, the 2D-element representation of a mask pattern may be generated in an iterative way, as described at least with reference to FIG. 4. For example, a mask feature from an initial mask pattern is obtained and a 2D-element representation is generated by assigning locations, associating, and adjusting the 2D elements to generate the 2D-element representation of the output mask pattern. The adjusting of the 2D elements may be based on a simulation associated with the lithography process (e.g., as described at least with reference to FIG. 3), OPC models, etc., or based on geometric properties of the mask pattern (e.g., widths, separations, etc.) and based on rules prescribed for OPC (e.g., adding serifs, bias, hammerhead, SRAFs, etc. on the main features).

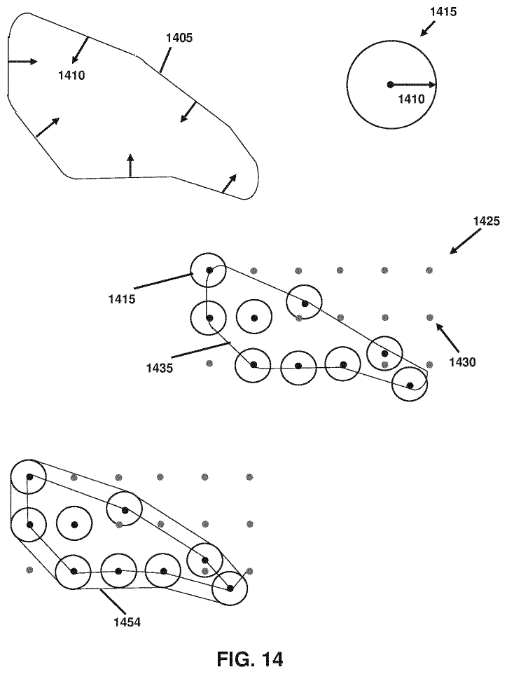

In a second method, the 2D-element representation of a mask pattern may be generated in a non-iterative way, as illustrated in FIG. 14. FIG. 14 illustrates generation of a 2D-element representation of a mask pattern for use in training a prediction model, consistent with various embodiments. For example, contour 1405 of a mask feature from an initial mask pattern is obtained. The contour 1405 is reduced (e.g., shrunk) by a specified amount to generate a shrunken contour 1435. The specified amount may be related to a geometrical parameter associated with a 2D element, such as a radius 1410 of a circle 1415. The 2D elements are then placed along the shrunken contour 1435 at or proximate the grid locations. In some embodiments, by shrinking the contour 1405 by an amount equal to the radius of the 2D element, and placing the 2D elements along the shrunken contour 1435 to generate a 2D-element representation 1425, the contour 1454 reconstructed from the 2D-element representation 1425 will be almost the same size and shape as the initial contour 1405 (e.g., as the reconstructed contour 1454 will extend outwards from the shrunken contour 1435 by an amount equal to the radius of the circle 1415). In some embodiments, the number of 2D elements that can be placed along the shrunken contour 1435 may depend on a resolution of the grid 1430. For example, the greater the resolution of the grid 1430, the greater the number of 2D elements that can be placed along the shrunken contour 1435, the finer the reconstructed contour 1454 will be, and more similar to the initial contour 1405 the reconstructed contour 1454 will be. In some embodiments, generating the 2D-element representation using the second method may be faster than and consumes lesser computing resources than generating using the first method.

After the 2D-element representation is generated (using the first method or the second method), information such as the presence information, the location information, displacement information, association information, etc. of the 2D elements from the 2D-element representation may be used to generate the set of images 1210a1-1210an.

Referring back to FIG. 13, at process P1310, the prediction model 850 is executed by inputting the training data (e.g., the set of input mask pattern images 1205 and the sets of images 1210). The prediction model 850 generates a set of images 1215a1-1215an based on the input mask pattern 1205a. The predicted set of images 1215a1-1215an is compared with the input set of images 1210a1-1210an in the training data and a cost function 1250 that is indicative of the difference between the predicted set of images 1215a1-1215an and the input set of images 1210a1-1210an, respectively, is computed. A determination is made whether the cost function 1250 is minimized. If the cost function 1250 is not minimized, the parameters of the prediction model 850 (e.g., weights and biases) are adjusted and the prediction model 850 is executed again to predict the set of images 1215a1-1215an. The processes of predicting the set of images, determining the cost function 1250, adjusting the prediction model parameters to reduce the cost function 1250 are repeated until the cost function 1250 is minimized. After the cost function 1250 is minimized, the prediction model 850 is considered to be trained, and the trained prediction model may be used to generate a set of images (e.g., the set of images 815) that are representative of a 2D-element representation of a mask pattern for any input mask pattern (e.g., input mask pattern 805), as described at least with reference to FIGS. 8 and 11.

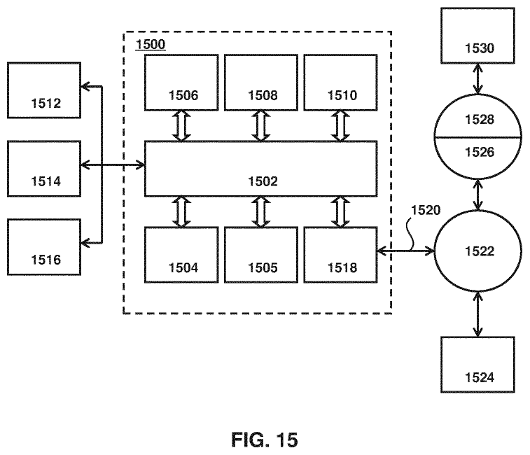

FIG. 15 is a block diagram that illustrates a computer system 1500 which can assist in implementing various methods and systems disclosed herein. The computer system 1500 may be used to implement any of the entities, components, modules, or services depicted in the examples of the figures (and any other entities, components, modules, or services described in this specification). The computer system 1500 may be programmed to execute computer program instructions to perform functions, methods, flows, or services (e.g., of any of the entities, components, or modules) described herein. The computer system 1500 may be programmed to execute computer program instructions by at least one of software, hardware, or firmware.

Computer system 1500 includes a bus 1502 or other communication mechanism for communicating information, and a processor 1504 (or multiple processors 1504 and 1505) coupled with bus 1502 for processing information. Computer system 1500 also includes a main memory 1506, such as a random access memory (RAM) or other dynamic storage device, coupled to bus 1502 for storing information and instructions to be executed by processor 1504. Main memory 1506 also may be used for storing temporary variables or other intermediate information during execution of instructions to be executed by processor 1504. Computer system 1500 further includes a read only memory (ROM) 1508 or other static storage device coupled to bus 1502 for storing static information and instructions for processor 1504. A storage device 1510, such as a magnetic disk or optical disk, is provided and coupled to bus 1502 for storing information and instructions.

Computer system 1500 may be coupled via bus 1502 to a display 1512, such as a cathode ray tube (CRT) or flat panel or touch panel display for displaying information to a computer user. An input device 1514, including alphanumeric and other keys, is coupled to bus 1502 for communicating information and command selections to processor 1504. Another type of user input device is cursor control 1516, such as a mouse, a trackball, or cursor direction keys for communicating direction information and command selections to processor 1504 and for controlling cursor movement on display 1512. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system 1500 in response to processor 1504 executing one or more sequences of one or more instructions contained in main memory 1506. Such instructions may be read into main memory 1506 from another computer-readable medium, such as storage device 1510. Execution of the sequences of instructions contained in main memory 1506 causes processor 1504 to perform the process steps described herein. One or more processors in a multi-processing arrangement may also be employed to execute the sequences of instructions contained in main memory 1506. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 1504 for execution. Such a medium may take many forms, including but not limited to, non-volatile media, volatile media, and transmission media. Non-volatile media include, for example, optical or magnetic disks, such as storage device 1510. Volatile media include dynamic memory, such as main memory 1506. Transmission media include coaxial cables, copper wire and fiber optics, including the wires that comprise bus 1502. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 1504 for execution. For example, the instructions may initially be borne on a magnetic disk of a remote computer. The remote computer can load the instructions into its dynamic memory and send the instructions over a telephone line using a modem. A modem local to computer system 1500 can receive the data on the telephone line and use an infrared transmitter to convert the data to an infrared signal. An infrared detector coupled to bus 1502 can receive the data carried in the infrared signal and place the data on bus 1502. Bus 1502 carries the data to main memory 1506, from which processor 1504 retrieves and executes the instructions. The instructions received by main memory 1506 may optionally be stored on storage device 1510 either before or after execution by processor 1504.

Computer system 1500 also preferably includes a communication interface 1518 coupled to bus 1502. Communication interface 1518 provides a two-way data communication coupling to a network link 1520 that is connected to a local network 1522. For example, communication interface 1518 may be an integrated services digital network (ISDN) card or a modem to provide a data communication connection to a corresponding type of telephone line. As another example, communication interface 1518 may be a local area network (LAN) card to provide a data communication connection to a compatible LAN. Wireless links may also be implemented. In any such implementation, communication interface 1518 sends and receives electrical, electromagnetic, or optical signals that carry digital data streams representing various types of information.

Network link 1520 typically provides data communication through one or more networks to other data devices. For example, network link 1520 may provide a connection through local network 1522 to a host computer 1524 or to data equipment operated by an Internet Service Provider (ISP) 1526. ISP 1526 in turn provides data communication services through the worldwide packet data communication network, now commonly referred to as the “Internet” 1528. Local network 1522 and Internet 1528 both use electrical, electromagnetic, or optical signals that carry digital data streams. The signals through the various networks and the signals on network link 1520 and through communication interface 1518, which carry the digital data to and from computer system 1500, are exemplary forms of carrier waves transporting the information.

Computer system 1500 can send messages and receive data, including program code, through the network(s), network link 1520, and communication interface 1518. In the Internet example, a server 1530 might transmit a requested code for an application program through Internet 1528, ISP 1526, local network 1522 and communication interface 1518. One such downloaded application may provide for the illumination optimization of the embodiment, for example. The received code may be executed by processor 1504 as it is received, or stored in storage device 1510, or other non-volatile storage for later execution. In this manner, computer system 1500 may obtain application code in the form of a carrier wave.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The terms “optimizing” and “optimization” as used herein refers to or means adjusting a patterning apparatus (e.g., a lithography apparatus), a patterning process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g., a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Aspects of the invention can be implemented in any convenient form. For example, an embodiment may be implemented by one or more appropriate computer programs which may be carried on an appropriate carrier medium which may be a tangible carrier medium (e.g., a disk) or an intangible carrier medium (e.g., a communications signal). Embodiments of the invention may be implemented using suitable apparatus which may specifically take the form of a programmable computer running a computer program arranged to implement a method as described herein. Thus, embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical, or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g., within a data center or geographically), or otherwise differently organized. The functionality described herein may be provided by one or more processors of one or more computers executing code stored on a tangible, non-transitory, machine-readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

Embodiments of the present disclosure can be further described by the following clauses.

1. A method for determining a mask pattern for use with a lithography process, the method comprising:
providing an input mask pattern corresponding to a target pattern to a prediction model; generating, using the prediction model, a 2D-element representation of an output mask pattern corresponding to the input mask pattern, wherein the 2D-element representation includes multiple 2D elements representing a mask feature of the output mask pattern and each 2D element defines an enclosed area; and
determining mask feature contours of the output mask pattern based on the 2D-element representation.

2. The method of clause 1, wherein the 2D-element representation includes a set of images that is indicative of location information of the 2D elements in the 2D-element representation.

3. The method of clause 2, wherein the location information includes information regarding grid locations assigned to the 2D elements and displacements of the 2D elements from the assigned grid locations.

4. The method of clause 2, wherein the set of images includes a binary image that is indicative of presence or absence of a 2D element at a specified grid location.

5. The method of clause 2, wherein the set of images includes:
a first image that is indicative of an amount of displacement of a 2D element from a specified grid location in a first direction, and
a second image that is indicative of an amount of displacement of the 2D element from the specified grid location in a second direction.

6. The method of clause 2, wherein the set of images includes:
a binary image that is indicative of presence or absence of a 2D element at a specified grid location;
a first image that is indicative of an amount of displacement of a 2D element from a specified grid location in a first direction; and
a second image that is indicative of an amount of displacement of the 2D element from the specified grid location in a second direction.

7. The method of clause 2 further comprising:
generating the 2D-element representation based on the set of images.

8. The method of clause 1, wherein each of the 2D elements are circular.

9. The method of clause 1, wherein each of the 2D elements is elliptical.

10. The method of clause 1, wherein each of the 2D elements are the same size.

11. The method of clause 1, wherein the 2D elements are of different sizes.

12. The method of clause 1, wherein determining the mask feature contours of the output mask pattern from the 2D-element representation includes:
associating the 2D elements based on association criteria to form a cluster that represents the mask feature; and
generating a contour of the cluster based on the 2D elements.

13. The method of clause 12, wherein the association criteria includes rule-based criteria.

14. The method of clause 13, wherein the rule-based criteria includes a distance-based criterion, which is indicative of a distance between two 2D elements.

15. The method of clause 12, wherein the 2D elements are associated based on association information derived from a binary image of the 2D-element representation, wherein the binary image indicates whether a 2D element at a specified location is associated with another 2D element at a neighboring location.

16. The method of clause 12, wherein the contour is an outer contour of the cluster that corresponds to an outer edge of the mask feature.

17. The method of clause 12, wherein the contour is an inner contour of the cluster that corresponds to an inner edge of the mask feature.

18. The method of clause 12 further comprising:
generating sub-areas of the contour by applying a polygon offsetting operation to pairs of the associated 2D elements; and
computing the union of the sub-areas, wherein the contour is the union of the sub-areas.

19. The method of clause 1 further comprising: optimizing the output mask pattern using an optical proximity correction process.

20. The method of clause 19 further comprising:
manufacturing a mask from the output mask pattern that includes the mask feature contours generated from the 2D elements.

21. The method of clause 1, wherein providing the input mask pattern includes:
obtaining a representation of the target pattern;
generating an image from the target pattern, wherein the image is representative of the input mask pattern; and
providing the image of the input mask pattern to the prediction model.

22. The method of clause 1 further comprising:
training the prediction model using training data to generate 2D-element representations, wherein the training data includes a set of input mask patterns and 2D-element representations of a set of output mask patterns corresponding to the set of input mask patterns.

23. The method of clause 22, wherein training the prediction model includes:
obtaining a first output mask pattern of the set of output mask patterns corresponding to a first input mask pattern of the set of input mask patterns;
obtaining a first 2D-element representation of the first output mask pattern; and
executing the prediction model to generate a specified 2D-element representation of the first output mask pattern based on the first input mask pattern and the first 2D-element representation.

24. The method of clause 23, wherein obtaining the first 2D-element representation includes:
assigning locations of a collection of 2D elements based on a shape of the first input mask pattern;
associating the collection of 2D elements based on association criteria to form a cluster that represents a specified mask feature of the first input mask pattern; and
adjusting the collection of 2D elements of the cluster to vary the specified mask feature.

25. The method of clause 24, wherein the adjusting is based on geometric properties of the first output mask pattern and based on rules prescribed for optimal proximity correction (OPC) process.

26. The method of clause 24, wherein the adjusting is based on a simulation associated with the lithography process.

27. The method of clause 24 further comprising:
generating a set of images that is indicative of location information of the collection of 2D elements in the first 2D-element representation.

28. The method of clause 23, wherein obtaining the first 2D-element representation includes:
shrinking a specified mask feature contour by a specified dimension associated with a 2D element to generate a shrinked contour; and
assigning locations of a collection of 2D elements along the shrinked contour such that a contour generated from the collection of 2D elements approximates the specified mask feature contour.

29. The method of clause 23, wherein the first 2D-element representation of the first mask pattern is derived from a level-set image of the first output mask pattern.

30. A method for training a prediction model to generate a 2D-element representation of a mask pattern for use with a lithography process, the method comprising:
obtaining a set of input mask patterns and a set of 2D-element representations of a set of output mask patterns corresponding to the set of input mask patterns as training data, wherein a 2D-element representation of the set of 2D-element representations includes multiple 2D elements representing a mask feature of the mask pattern and each 2D element defines at least partially enclosed area; and
training the prediction model using the training data to generate 2D-element representations.

31. The method of clause 30, wherein training the prediction model includes:
obtaining a first output mask pattern of the set of output mask patterns corresponding to a first input mask pattern of the set of input mask patterns;
obtaining a first 2D-element representation of the first output mask pattern; and
executing the prediction model to generate a specified 2D-element representation of the first output mask pattern based on the first input mask pattern and the first 2D-element representation.

32. The method of clause 31, wherein training the prediction model includes:
training the prediction model until a cost function is reduced, wherein the cost function is indicative of difference between (a) a specified 2D-element representation generated by the prediction model and (b) the first 2D-element representation.

33. The method of clause 31, wherein obtaining the first 2D-element representation includes:
assigning locations of a collection of 2D elements based on a shape of the first input mask pattern;
associating the collection of 2D elements based on association criteria to form a cluster that represents a specified mask feature of the first input mask pattern; and
adjusting the collection of 2D elements of the cluster to vary the specified mask feature.

34. The method of clause 33, wherein the adjusting is based on geometric properties of the first output mask pattern and based on rules prescribed for optimal proximity correction (OPC) process.

35. The method of clause 33, wherein the adjusting is based on a simulation associated with the lithography process.

36. The method of clause 33 further comprising:
generating a set of images that is indicative of location information of the collection of 2D elements in the first 2D-element representation.

37. The method of clause 33, wherein obtaining the first 2D-element representation includes:
shrinking a specified mask feature contour by a specified dimension associated with a 2D element to generate a shrinked contour; and
assigning locations of a collection of 2D elements along the shrinked contour such that a contour generated from the collection of 2D elements approximates the specified mask feature contour.

38. The method of clause 31, wherein the first 2D-element representation of the first mask pattern is derived from a level-set image of the first output mask pattern.

39. The method of clause 30 further comprising:
providing an input mask pattern corresponding to a target pattern to the prediction model; generating, using the prediction model, a predicted 2D-element representation of an output mask pattern; and
determining mask feature contours of the output mask pattern based on the predicted 2D-element representation.

40. The method of clause 39 further comprising: optimizing the output mask pattern using an optical proximity correction process to generate a mask pattern.

41. The method of clause 40 further comprising:
manufacturing a mask from the mask pattern that includes the mask feature contours generated from the 2D elements.

42. An apparatus, the apparatus comprising:
a memory storing a set of instructions; and
a processor configured to execute the set of instructions to cause the apparatus to perform a method of any of the above clauses.

43. A non-transitory computer-readable medium having instructions recorded thereon, the instructions when executed by a computer implementing the method of any of the above clauses.

The reader should appreciate that the present application describes several inventions. Rather than separating those inventions into multiple isolated patent applications, these inventions have been grouped into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such inventions or all aspects of such inventions.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C. Expressions such as “at least one of” do not necessarily modify an entirety of a following list and do not necessarily modify each member of the list, such that “at least one of A, B, and C” should be understood as including only one of A, only one of B, only one of C, or any combination of A, B, and C. The phrase “one of A and B” or “any one of A and B” shall be interpreted in the broadest sense to include one of A, or one of B.

The descriptions herein are intended to be illustrative, not limiting. Thus, it will be apparent to one skilled in the art that modifications may be made as described without departing from the scope of the claims set out below.

1. A non-transitory computer-readable medium having recorded instructions, the instructions, when executed by a computer system, configured to cause the computer system to at least:
provide an input mask pattern corresponding to a target pattern to a prediction model;
generate, using the prediction model, a 2D-element representation of an output mask pattern corresponding to the input mask pattern, wherein the 2D-element representation includes multiple 2D elements representing a mask feature of the output mask pattern and each 2D element defines an enclosed area; and
determine, based on the 2D-element representation, one or more mask feature contours of the output mask pattern for use with a lithography process.

2. The medium of claim 1, wherein the 2D-element representation includes a set of images that is indicative of location information of the 2D elements in the 2D-element representation.

3. The medium of claim 2, wherein the location information includes information regarding grid locations assigned to the 2D elements and displacements of the 2D elements from the assigned grid locations.

4. The medium of claim 2, wherein the set of images includes a binary image that is indicative of presence or absence of a 2D element at a specified grid location.

5. The medium of claim 2, wherein the set of images includes:
a first image that is indicative of an amount of displacement of a 2D element from a specified grid location in a first direction, and
a second image that is indicative of an amount of displacement of the 2D element from the specified grid location in a second direction,
wherein the instructions are further configured to cause the computer system to generate the 2D-element representation based on the set of images.

6. The medium of claim 1, wherein each of the 2D elements are circular or elliptical.

7. The medium of claim 1, wherein the instructions configured to cause the computer system to determine the one or more mask feature contours of the output mask pattern from the 2D-element representation are further configured to cause the computer system to:
associate the 2D elements based on association criteria to form a cluster that represents the mask feature; and
generate a contour of the cluster based on the 2D elements, wherein the contour is an outer contour of the cluster that corresponds to an outer edge of the mask feature or an inner contour of the cluster that corresponds to an inner edge of the mask feature.

8. The medium of claim 7, wherein the association criteria is related to a distance between two 2D elements.

9. The method of claim 7, wherein the 2D elements are associated based on association information derived from a binary image of the 2D-element representation, wherein the binary image indicates whether a 2D element at a specified location is associated with another 2D element at a neighboring location.

10. The medium of claim 7, wherein the instructions are further configured to cause the computer system to:
generate sub-areas of the contour by application of polygon offsetting operation to pairs of the associated 2D elements; and
determine the union of the sub-areas, wherein the contour is the union of the sub-areas.

11. The medium of claim 1, wherein the instructions configured to cause the computer system to provide the input mask pattern are further configured to cause the computer system to:
obtain a representation of the target pattern;
generate an image from the target pattern, wherein the image is representative of the input mask pattern; and
provide the image of the input mask pattern to the prediction model, and wherein the instructions are further configured to cause the computer system to optimize the output mask pattern using an optical proximity correction process.

12. The medium of claim 1, wherein the instructions are further configured to cause the computer system to train the prediction model using training data to generate 2D-element representations, wherein the training data includes a set of input mask patterns and 2D-element representations of a set of output mask patterns corresponding to the set of input mask patterns.

13. The medium of claim 12, wherein the instructions configured to cause the computer system to train the prediction model are further configured to cause the computer system to:
obtain a first output mask pattern of the set of output mask patterns corresponding to a first input mask pattern of the set of input mask patterns;
obtain a first 2D-element representation of the first output mask pattern; and
execute the prediction model to generate a specified 2D-element representation of the first output mask pattern based on the first input mask pattern and the first 2D-element representation, and
wherein the instructions configured to cause the computer system to obtain the first 2D-element representation are further configured to cause the computer system to:
assign locations of a collection of 2D elements based on a shape of the first input mask pattern;
associate the collection of 2D elements based on association criteria to form a cluster that represents a specified mask feature of the first input mask pattern; and
adjust the collection of 2D elements of the cluster to vary the specified mask feature, wherein the adjustment is based on one or more geometric properties of the first output mask pattern and based on one or more rules prescribed for optimal proximity correction (OPC) process, or wherein the adjustment is based on a simulation associated with the lithography process.

14. The medium of claim 13, wherein the instructions are further configured to cause the computer system to generate a set of images that is indicative of location information of the collection of 2D elements in the first 2D-element representation,
wherein the instructions configured to cause the computer system to obtain the first 2D-element representation are further configured to cause the computer system to:
shrink a specified mask feature contour by a specified dimension associated with a 2D element to generate a shrinked contour; and
assign locations of a collection of 2D elements along the shrinked contour such that a contour generated from the collection of 2D elements approximates the specified mask feature contour.

15. The medium of claim 13, wherein the first 2D-element representation of the first mask pattern is derived from a level-set image of the first output mask pattern.

16. A non-transitory computer-readable medium having recorded instructions, the instructions, when executed by a computer system, configured to cause the computer system to at least:
obtain a set of input mask patterns and a set of 2D-element representations of a set of output mask patterns corresponding to the set of input mask patterns as training data, wherein a 2D-element representation of the set of 2D-element representations includes multiple 2D elements representing a mask feature of the mask pattern and each 2D element defines an at least partially enclosed area; and
train, using the training data, a prediction model configured to generate, using an input mask pattern, a 2D-element representation for use with a lithography process.

17. The medium of claim 16, wherein the instructions configured to cause the computer system to train the prediction model are further configured to cause the computer system to:
obtain a first output mask pattern of the set of output mask patterns corresponding to a first input mask pattern of the set of input mask patterns;
obtain a first 2D-element representation of the first output mask pattern; and
execute the prediction model to generate a specified 2D-element representation of the first output mask pattern based on the first input mask pattern and the first 2D-element representation.

18. The medium of claim 17, wherein the instructions configured to cause the computer system to train the prediction model are further configured to cause the computer system to train the prediction model until a cost function is reduced, wherein the cost function is indicative of difference between (a) a specified 2D-element representation generated by the prediction model and (b) the first 2D-element representation.

19. The medium of claim 17, wherein the instructions configured to cause the computer system to obtain the first 2D-element representation are further configured to cause the computer system to:
assign locations of a collection of 2D elements based on a shape of the first input mask pattern;
associate the collection of 2D elements based on association criteria to form a cluster that represents a specified mask feature of the first input mask pattern; and
adjust the collection of 2D elements of the cluster to vary the specified mask feature.

20. The medium of claim 17, wherein the first 2D-element representation of the first mask pattern is derived from a level-set image of the first output mask pattern.
